(19) United States
(12) Patent Application Publication
(10) Pub. No.: US 2018/0282869 A1
(43) Pub. Date: Oct. 4, 2018

(54) SHOWER PLATE, SUBSTRATE PROCESSING APPARATUS AND METHOD FOR PROCESSING SUBSTRATE

(71) Applicant: ASM IP Holding B.V., Almere (NL)

(72) Inventor: Yoshio SUSA, Tokyo (JP)

(73) Assignee: ASM IP Holding B.V., Almere (NL)

(21) Appl. No.: 15/471,376

(22) Filed: Mar. 28, 2017

(51) Int. Cl. C23C 16/455; C23C 16/503; C23C 16/505; C23C 16/458; H01J 37/32

(52) U.S. Cl. CPC C23C 16/45565; C23C 16/503; C23C 16/505; C23C 16/4585; H01L 21/02274; H01J 37/3244; H01J 37/3266; H01J 37/32715; H01J 37/32082

(57) ABSTRACT

A shower plate includes a plate part provided with a plurality of through holes and formed of a conductor, a ring-shaped part connected to an outer edge of the plate part, surrounding the plate part and formed of a conductor, and a lead wire embedded in the ring-shaped part and surrounding the plate part in plan view.

### BACKGROUND OF THE INVENTION

### Field of the Invention

The present invention relates to a shower plate used for processing a substrate, a substrate processing apparatus and a method for processing the substrate.

### Background Art

JP2009-152603 discloses a plasma CVD apparatus having a cleaning function has an improved shower plate with holes having a uniform cross-sectional area to yield a high cleaning rate. The shower plate may serve as an electrode, and may have an electrically conductive extension connected to a power source. The shower plate, through which both cleaning gas and reaction source gas flow, may include a hole machined surface area with a size different than conventionally used to ensure a good film thickness uniformity during a deposition process. The size of the hole machined surface area may vary based on the size of a substrate to be processed, or the size of the entire surface of the shower plate.

JP2016-122654 discloses a method and an apparatus for plasma processing of substrates. In this disclosure, a processing chamber has a substrate support and a lid assembly facing the substrate support. The lid assembly has a plasma source that includes an inductive coil disposed within a conductive plate, and may include nested conductive rings. The inductive coil is substantially coplanar with the conductive plate, and insulated from the conductive plate by an insulator that fits within a channel formed in the conductive plate or nests within the conductive rings. A field concentrator is provided around the inductive coil, and insulated from the inductive coil by isolators. The plasma source is supported from a conductive support plate. A gas distributor supplies gas to the chamber through a central opening of the support plate and to the plasma source from a conduit disposed through the conductive plate.

The shower plate in JP2009-152603 is an electrode of a parallel planar plasma CVD apparatus. In the apparatus configuration of JP2009-152603, relative to a plasma density directly below a central part of the shower plate, a plasma density directly below the outside of the shower plate that surrounds the central part sometimes decreases. This results in a problem that it is not possible to perform uniform plasma processing on the entire surface of the substrate. For example, film formation becomes insufficient at and around an outer edge of a wafer, and in-plane uniformity of film thickness and film quality become degraded.

### SUMMARY OF THE INVENTION

The present invention has been implemented to solve the above-described problems and it is an object of the present invention to provide a shower plate, a substrate processing apparatus and a method for processing a substrate capable of applying uniform plasma processing to the substrate.

The features and advantages of the present invention may be summarized as follows.

According to one aspect of the present invention, a shower plate includes a plate part provided with a plurality of through holes and formed of a conductor, a ring-shaped part connected to an outer edge of the plate part, surrounding the plate part and formed of a conductor, and a lead wire embedded in the ring-shaped part and surrounding the plate part in plan view.

According to another aspect of the present invention, a substrate processing apparatus includes a chamber, a susceptor provided in the chamber, a shower plate having a plate part provided with a plurality of through holes and formed of a conductor, a ring-shaped part connected to an outer edge of the plate part, surrounding the plate part and formed of a conductor and a lead wire embedded in the ring-shaped part and surrounding the plate part and the susceptor in plan view, the shower plate being provided so as to face the susceptor in the chamber, and a DC power supply that supplies a direct current to the lead wire.

According to another aspect of the present invention, a method for processing a substrate includes a mounting step of providing the substrate on a susceptor, and a plasma step of applying RF power to a shower plate provided on the susceptor, the shower plate having a plate part provided with a plurality of through holes and formed of a conductor, and a ring-shaped part connected to an outer edge of the plate part, surrounding the plate part and formed of a conductor, supplying a gas onto the substrate via the plurality of through holes and thereby generating plasma on the substrate. In the plasma step, a direct current is passed through a lead wire embedded in the ring-shaped part and surrounding the plate part in plan view to thereby form a magnetic field directly above an outer edge of the substrate.

Other and further objects, features and advantages of the invention will appear more fully from the following description.

### BRIEF DESCRIPTION OF THE DRAWINGS

FIG. 1 is a cross-sectional view of a substrate processing apparatus according to a first embodiment;

FIG. 2 is a plan view of the lead wire and the susceptor;

FIG. 3 is an enlarged cross-sectional view of the shower plate and the susceptor;

FIG. 4 is a cross-sectional view of the shower plate and the susceptor with plasma;

FIG. 5 is a diagram illustrating a plasma density;

FIG. 6 is a cross-sectional view of the shower plate and the susceptor according to a second embodiment; and

FIG. 7 is a cross-sectional view of the shower plate and the susceptor according to a third embodiment.

### DETAILED DESCRIPTION OF THE PREFERRED EMBODIMENTS

A shower plate, a substrate processing apparatus and a method for processing a substrate according to embodiments of the present invention will be described with reference to the accompanying drawings. The same or corresponding components will be assigned the same reference numerals and duplicate description may be omitted.

### First Embodiment

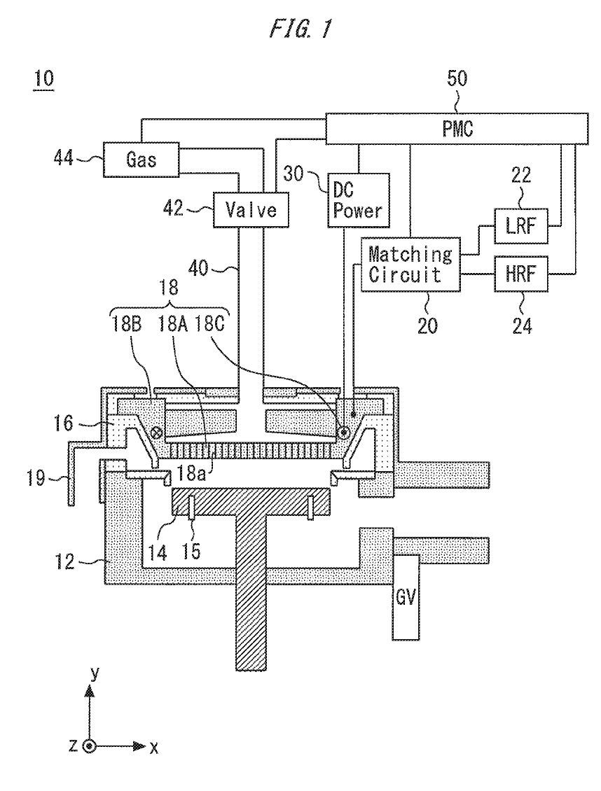

FIG. 1 is a cross-sectional view of a substrate processing apparatus 10 according to a first embodiment. The substrate processing apparatus 10 is a parallel planar plasma processing apparatus. The substrate processing apparatus 10 is provided with a chamber 12. The chamber 12 is called a “reactor chamber.” A susceptor 14 is provided in the chamber 12. The susceptor 14 is a part on which a substrate is mounted. In some embodiments, a resistance heating apparatus is embedded in the susceptor 14. The susceptor 14 is preferably electrically grounded. The susceptor 14 is provided with susceptor pins 15 protruding from the susceptor 14 or housed in the susceptor 14 so as to be used to lift/lower the substrate.

An exhaust duct 16 formed of, for example, an insulator is provided above the chamber 12. The exhaust duct 16 is formed into a ring shape so as to surround the susceptor 14 in plan view. A gas to be used for substrate processing is guided into the exhaust duct 16, then passes through an exhaust pipe 19 and is exhausted to the outside.

A shower plate 18 is provided above the exhaust duct 16. The shower plate 18 is provided with a plate part 18A, a ring-shaped part 18B and a lead wire 18C. The plate part 18A is a conductor provided with a plurality of through holes 18a. The through holes 18a penetrate the plate part 18A in a y-axis direction. The ring-shaped part 18B is a conductor connected to an outer edge of the plate part 18A and surrounding the plate part 18A. The plate part 18A and the ring-shaped part 18B are made of aluminum or an aluminum alloy or another appropriate metal. The lead wire 18C is embedded in the ring-shaped part 18B. The lead wire 18C surrounds the plate part 18A in plan view. The lead wire 18C preferably surrounds the susceptor 14 in plan view. The lead wire 18C is preferably covered with an insulating coat so as to be electrically insulated from the ring-shaped part 18B.

In the chamber 12, the susceptor 14 and the shower plate 18 face each other. The shower plate 18 and the susceptor 14 provide a structure with a pair of parallel flat plates. That is, the shower plate 18 and the susceptor 14 provide parallel planar electrodes.

In order to generate plasma, high frequency power supplies 22 and 24 are electrically connected to the plate part 18A and the ring-shaped part 18B via a matching circuit 20. The high frequency power supplies 22 and 24 supply RF power to the plate part 18A and the ring-shaped part 18B. The high frequency power supplies 22 and 24 apply electric power at a frequency of, for example, several hundreds of kHz to several tens of MHz to the plate part 18A and the ring-shaped part 18B. To improve controllability of film quality, the high frequency power supply 22 preferably supplies a low frequency component and the high frequency power supply 24 preferably supplies a high frequency component.

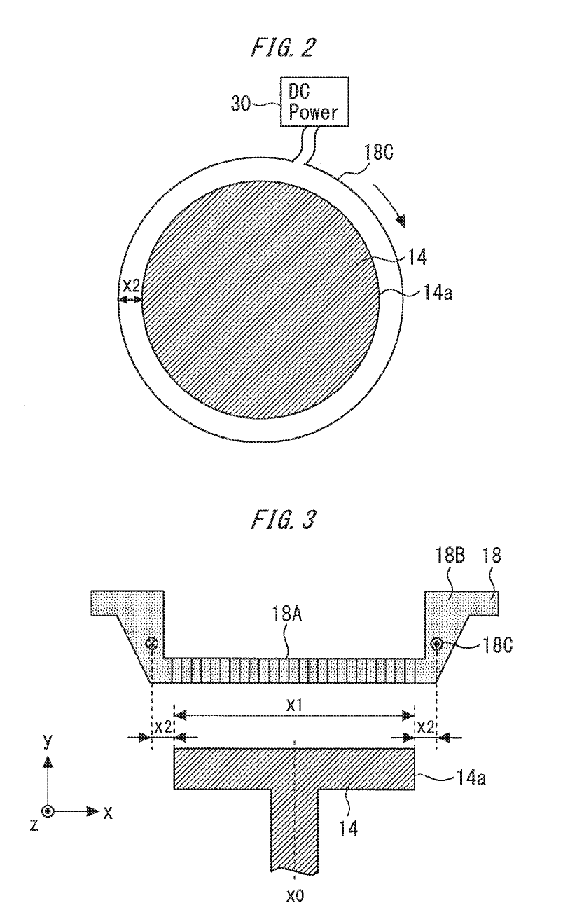

A DC power supply 30 is connected to the lead wire 18C to supply a direct current to the lead wire 18C. The DC power supply 30 supplies a direct current of, for example, on the order of 1 A to the lead wire 18C. FIG. 2 is a plan view of the lead wire 18C and the susceptor 14. The lead wire 18C is provided in a ring shape so as to surround the susceptor 14. A distance X2 between the lead wire 18C and an outer edge 14a of the susceptor 14 is, for example, on the order of 5 to 10 mm. For this reason, the lead wire 18C is located 5 to 10 mm outside the outer edge 14a of the susceptor 14. An arrow in FIG. 2 denotes a direction of direct current flow of the lead wire 18C. The DC power supply 30 causes a direct current to flow through the lead wire 18C in a clockwise direction as indicated by the arrow.

Now, FIG. 1 will be described again. A gas supply pipe 40 is connected to a top of the plate part 18A. A valve 42 is provided at some midpoint of the gas supply pipe 40. The valve 42 can open/close the gas supply pipe 40. Furthermore, a gas source 44 that supplies a gas is connected to the gas supply pipe 40. The gas source 44 supplies various gases to be used for processing of the substrate. Examples of such gas include a material gas, a reaction gas and a purge gas. The gas source 44 can supply all kinds of known gases to be used to generate plasma. A gas is supplied to a position directly above the susceptor 14 from the gas source 44 through the gas supply pipe 40, a space directly above the plate part 18A and the through holes 18a.

The high frequency power supplies 22 and 24, the matching circuit 20, the DC power supply 30, the valve 42 and the gas source 44 are connected to a PMC (process module controller) 50. The PMC 50 controls operations of the high frequency power supplies 22 and 24, the matching circuit 20, the DC power supply 30, the valve 42 and the gas source 44 based on a prescribed recipe.

FIG. 3 is an enlarged view of the shower plate 18 and the susceptor 14. When processing a 300 mm wafer, a width X1 of the susceptor 14 is, for example, 302 to 304 mm. A distance X2 between the outer edge 14a of the susceptor 14 and the lead wire 18C in a horizontal direction is, for example, on the order of 5 to 10 mm Therefore, the lead wire 18C is provided not directly above the susceptor 14 but outside a position directly above the susceptor 14. In FIG. 3, the lead wires 18C are located one on each of left and right sides of the ring-shaped part 18B. A direct current flows through the right-side lead wire 18C toward the front direction of the figure and flows through the left-side lead wire 18C toward the back direction of the figure.

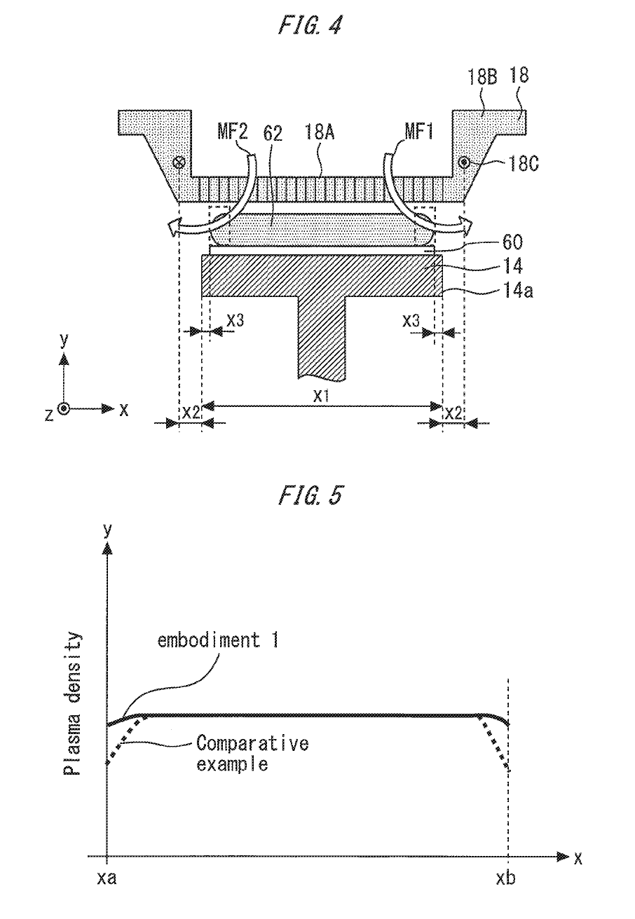

A method for processing a substrate using the substrate processing apparatus 10 will be described. FIG. 4 is a cross-sectional view of the shower plate 18 and the susceptor 14 where plasma processing on a substrate is in progress. First, a substrate 60 is mounted on the susceptor 14. This step is called a “mounting step.” The substrate 60 is, for example, a 300 mm wafer. A distance between an outer edge of the substrate 60 and the outer edge 14a of the susceptor 14 in the horizontal direction is, for example, on the order of 1 to 2 mm. Therefore, a distance X3 in FIG. 4 is, for example, 1 to 2 mm.

Next, the process proceeds to a plasma step. In the plasma step, plasma 62 is generated above the substrate 60 by supplying a gas onto the substrate 60 via the plurality of through holes 18a while applying RF power to the plate part 18A and the ring-shaped part 18B. More specifically, the PMC 50 operates the high frequency power supplies 22 and 24, and thereby applies RF power to the plate part 18A and the ring-shaped part 18B. Furthermore, the PMC 50 controls the gas source 44 and the valve 42, and thereby supplies a prescribed gas onto the substrate 60.

In the plasma step, a direct current is made to flow through the lead wire 18C in addition to the above-described application of RF power and gas supply. More specifically, a direct current of on the order of several A is made to flow from the DC power supply 30 into the lead wire 18C. The direct current flowing through the lead wire 18C is, for example, 1 A. Then, a direct current in a positive z-axis direction flows through the right-side lead wire 18C and a direct current in a negative z-axis direction flows through the left-side lead wire 18C in FIG. 4. A magnetic field MF1 is formed by the direct current flowing through the right-side lead wire 18C and a magnetic field MF2 is formed by the direct current flowing through the left-side lead wire 18C. The direction of the magnetic field MF1 is a counterclockwise direction and the direction of the magnetic field MF2 is a clockwise direction.

Thus, it is possible to form a magnetic field directly above the outer edge of the substrate 60 by passing a direct current through the lead wire 18C. This magnetic field allows a magnetic force to be exerted to the plasma 62. More specifically, the magnetic field provided is stronger directly above the outer edge of the substrate 60 and its vicinity than at a position directly above the center of the substrate 60. Furthermore, the lead wire 18C is located by a distance X2+X3 outside the outer edge of the substrate 60. Thus, it is possible to form a magnetic field having a vertically downward component directly above the outer edge of the substrate 60 by passing a direct current through the lead wire 18C. As is shown by the magnetic fields MF1 and MF2 in FIG. 4, the magnetic field generated directly above the outer edge of the substrate 60 by passing the direct current through the lead wire 18C has a “horizontal component” and a “vertical component.” The “horizontal component” is a component in a direction opposite to the center of the substrate. The “vertical component” is a component in a vertically downward direction.

FIG. 5 is a diagram illustrating a plasma density. A reference character “xa” denotes a position directly above a left end of the substrate 60 and reference character “xb” denotes a position directly above a right end of the substrate 60. When the substrate 60 is a 300 mm wafer, the distance from “xa” to “xb” is 300 mm. The vertical axis in FIG. 5 shows a plasma density. In FIG. 5, a solid line shows a plasma density generated at the substrate processing apparatus 10 according to the first embodiment and a broken line shows a plasma density according to a comparative example. The substrate processing apparatus according to the comparative example has a configuration in which the lead wire 18C is removed from the substrate processing apparatus 10. In the case of the comparative example, a significant decrease in the plasma density is observed at a position directly above an end portion compared to a position directly above the center of the substrate. This is assumed to be mainly attributable to the fact that electrons located in the vicinity of a position directly above the outer edge of the substrate at the beginning of plasma generation are attracted to cations existing directly above the center of the substrate at a high density and moved toward directly above the center of the substrate.

In contrast, according to the substrate processing apparatus 10 of the first embodiment, a magnetic field is formed mainly in a region directly above the outer edge of the substrate 60 by passing a direct current through the lead wire 18C. This magnetic field causes electrons to move so as to wind around magnetic lines of force. This motion is called “cyclotron motion.” Causing the magnetic field to trap electrons in the region directly above the outer edge of the substrate 60 prevents electrons from being attracted to positions directly above the center of the substrate 60. Note that the outer edge of the substrate 60 has a certain width and the “region directly above the outer edge” has a doughnut-shaped region having a certain width in plan view. The “region directly above the outer edge” is, for example, a region enclosed by the broken line in FIG. 4.

Thus, by preventing electrons in the region directly above the outer edge of the substrate 60 from being attracted to positions directly above the center of the substrate 60, it is possible to prevent the plasma density in the region directly above the outer edge of the substrate from decreasing. It is thereby possible to keep substantially constant the plasma density directly above the substrate 60. Thus, uniform plasma processing can be applied to the substrate 60. Moreover, the shower plate 18 according to the first embodiment can be simply manufactured by only providing the lead wire 18C for the shower plate having two conventionally known functions of gas supply and RF application.

The magnetic field provided in the region directly above the outer edge of the substrate 60 has a “horizontal component” and a “vertical component.” According to an experiment conducted by the inventor, the vertical component of the magnetic field is particularly important to keep electrons in the region directly above the outer edge of the substrate 60. In order to provide a vertical component of sufficient intensity in the region directly above the outer edge of the substrate 60, X2+X3 in FIG. 4 must not be 0. In other words, a certain distance needs to be kept between the outer edge of the substrate 60 and the lead wire 18C in plan view. A sufficient vertical component can be provided by setting X2+X3 to, for example, on the order of 5 to 10 mm. Note that X3 is quite a small value and includes a slight difference depending on the substrate processing apparatus, and so X2 may be set to 5 to 10 mm.

The horizontal component of the magnetic field is a component in a direction opposite to the center of the substrate 60. That is, the horizontal component is a component in a negative x-axis direction on the left side of FIG. 4 and in a positive x-axis direction on the right side of FIG. 4. Since these horizontal components act in a direction in which the plasma 62 is widened, this is considered to contribute to applying uniform plasma processing to the substrate 60.

A lead wire may be provided on a side wall of the chamber 12 and a magnetic field may be formed in a region directly above the outer edge of the substrate 60 by using the lead wire. However, since the side face of the chamber 12 is distanced from the substrate 60, it is difficult to form a magnetic field of sufficient intensity in the region directly above the outer edge of the substrate 60. Although this problem may be solved by passing a high direct current through the lead wire, a temperature rise in the apparatus through which the high direct current flows may cause various harmful effects. In contrast, since the substrate processing apparatus 10 according to the first embodiment of the present invention embeds the lead wire 18C in the ring-shaped part 18B of the shower plate 18, the distance between the lead wire 18C and the substrate 60 is small. It is thereby possible to form a magnetic field of sufficient intensity in the region directly above the outer edge of the substrate 60 without supplying a high direct current to the lead wire 18C.

The shower plate, the substrate processing apparatus and the method for processing a substrate according to the first embodiment of the present invention can be modified in various ways without losing features thereof. For example, processing contents of the substrate are not limited to film formation, but all kinds of processing using plasma may be adopted. The above-described specific numerical values are examples. The modifications described in the first embodiment are also applicable to shower plates, substrate processing apparatuses and methods for processing a substrate according to the following embodiments. Note that since the shower plates, substrate processing apparatuses and methods for processing a substrate according to the following embodiments have many points similar to those of the first embodiment, the description will focus on differences from the first embodiment.

### Second Embodiment

FIG. 6 is a cross-sectional view of the shower plate 18 and the susceptor 14 according to a second embodiment. A plurality of lead wires 18C are provided in a cross-sectional view. The number of windings of the lead wire 18C ranges 10 to 100, for example. One lead wire may be wound a plurality of times or a plurality of individual lead wires may be provided. A plurality of lead wires 18C appear in a cross-sectional view in all cases. When a plurality of lead wires 18C are provided, it is possible to form a magnetic field of sufficient intensity in a region directly above the outer edge of the substrate by passing a direct current of, for example, 10 to 100 mA through the respective lead wires in the plasma step. Providing a plurality of turns of the lead wire 18C makes it possible to reduce a direct current flowing through the lead wire 18C, and thereby prevent a temperature rise of the apparatus.

### Third Embodiment

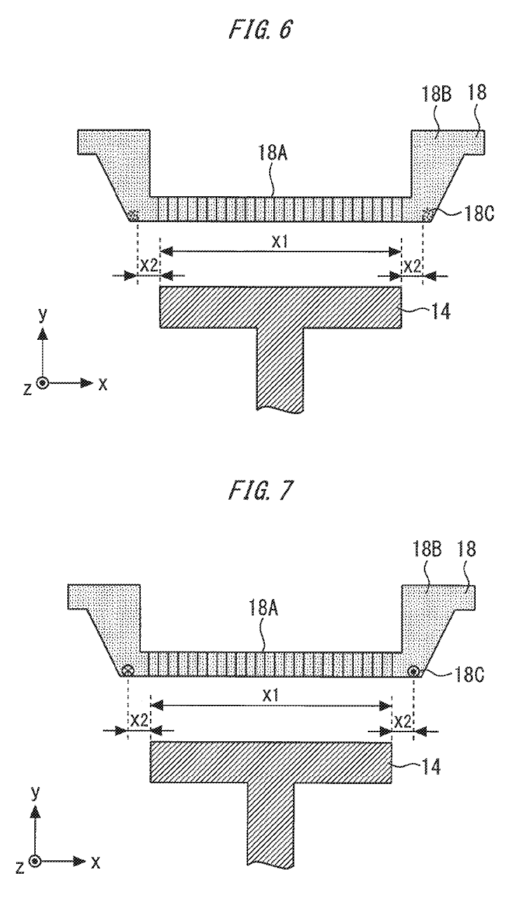

FIG. 7 is a cross-sectional view of the shower plate 18 and the susceptor 14 according to a third embodiment. The lead wire 18C is embedded in a bottom end portion of the ring-shaped part 18B. The “bottom end portion” of the ring-shaped part 18B is a region including the bottom end of the ring-shaped part 18B. Therefore, the lead wire 18C according to the third embodiment is located in a negative y-axis direction more than the lead wire 18C according to the first embodiment. Providing the lead wire 18C in the bottom end portion of the ring-shaped part 18B makes it possible to reduce the distance between the lead wire 18C and the substrate in the vertical direction while keeping the distance between the lead wire 18C and the substrate in the horizontal direction. Therefore, it is possible to supply a stronger magnetic field than that of the first embodiment to the region directly above the outer edge of the substrate. Since the lead wire 18C is moved downward, it is possible to strengthen the vertical component of the magnetic field in the region directly above the outer edge of the substrate.

The plasma density in the region directly above the outer edge of the substrate has been studied in the first to third embodiments. However, since there is not a substantial positional difference between the outer edge of the substrate and the outer edge of the susceptor, the same discussions as those described above will hold true even when the “region directly above the outer edge of the substrate” is read as the “region directly above the outer edge of the susceptor.” Furthermore, the features described in the first to third embodiments may be used in combination.

According to the present invention, a direct current is made to flow through a lead wire provided in the shower plate and a magnetic field is formed in an outside part of plasma. It is thereby possible to apply uniform plasma processing to the substrate.

Obviously many modifications and variations of the present invention are possible in the light of the above teachings. It is therefore to be understood that within the scope of the appended claims the invention may be practiced otherwise than as specifically described.

1. A shower plate comprising:
a plate part provided with a plurality of through holes and formed of a conductor;
a ring-shaped part connected to an outer edge of the plate part, surrounding the plate part and formed of a conductor; and
a lead wire embedded in the ring-shaped part and surrounding the plate part in plan view.

2. The shower plate according to claim 1, wherein the lead wire is provided in plurality.

3. The shower plate according to claim 1, wherein the lead wire is embedded in a bottom end portion of the ring-shaped part.

4. The shower plate according to claim 1, wherein the lead wire is covered with an insulating coat and thereby electrically insulated from the ring-shaped part.

5.-14. (canceled)
